(19) United States
(12) Patent Application Publication
(10) Pub. No.: US 2025/0183617 A1
(43) Pub. Date: Jun. 5, 2025

(54) METHOD FOR MANUFACTURING AN OPTOELECTRONIC DEVICE COMPRISING AN INTERMETALLIC COMPOUND

(71) Applicant: COMMISSARIAT A L'ENERGIE ATOMIQUE ET AUX ENERGIES ALTERNATIVES, Paris (FR)

(72) Inventors: Clément CARDOUX, Grenoble Cedex 09 (FR); Eric KROEMER, Grenoble Cedex 09 (FR); Vincent REBOUD, Grenoble Cedex 09 (FR); Philippe RODRIGUEZ, Grenoble Cedex 09 (FR); Alexei TCHELNOKOV, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/959,923

(22) Filed: Nov. 26, 2024

(30) Foreign Application Priority Data
Nov. 30, 2023 (FR) 2313376

(51) Int. Cl. H01S 5/042; H01S 5/02

(52) U.S. Cl. CPC H01S 5/0421; H01S 5/0217; H01S 5/04252; H01S 5/04256

(57) ABSTRACT

The method of the invention comprises an epitaxy of a layer of interest made of GeSn on a growth layer comprising Ge, having a concentration of tin lower than that of the layer of interest; a formation of an active region in the layer of interest, having a surface extent smaller than a first maximum surface area; a removal of a part of the growth layer so that the interface between the growth layer and the layer of interest facing the active region is less than a second maximum surface area or null; a formation of a metallic portion including Ti or NiPt on a part of the layer of interest;

a heating in a furnace to a temperature strictly greater than the epitaxy temperature, to create an intermetallic compound from the metallic portion; the first and second maximum surface areas being such that the tin in the active region does not segregate.

### TECHNICAL FIELD

The field of the invention is that of creating a microelectronic or optoelectronic device containing an alloy of germanium and tin comprising an intermetallic compound, in particular in the form of an intermetallic compound of NiPt and of GeSn, or of an intermetallic compound of Ti and of GeSn. The intermetallic compound is for example a part of an ohmic contact of the microelectronic device.

### PRIOR ART

The materials containing an alloy of germanium and tin (GeSn) can be used in light sources or photodetectors operating in the range of wavelengths of the mid-wavelength infrareds (called MWIR), for example at wavelengths greater than 1.6 μm. Several of these devices are generally manufactured in parallel on a plate on which at least one layer containing GeSn rests. They have in particular uses in the field of optical connections between chips or microprocessors, of optical sensors of chemical species, or of imagers.

The light sources and the photodetectors containing an alloy of germanium and tin (GeSn) comprise at least one active region containing GeSn in which photons are respectively emitted or absorbed. It is generally electrically connected to a reading or control or power supply circuit comprising metal lines and/or vias. It is therefore necessary to create an electric connection between the material containing GeSn and the circuit. Very often, the electric connection comprises an ohmic contact, in physical contact with the material containing GeSn. By definition, an electric contact is called ohmic if a variation in the electric current passing through it is proportional to a variation in a difference in potential applied to its terminals.

One way to create a not-very-resistive ohmic contact is to form an intermetallic compound of GeSn. The intermetallic compound has other advantages, including the following: good adhesion of the contact, low resistivity, good predictability of the resistance of the ohmic contact and a compatibility with the CMOS methods.

An intermetallic compound of GeSn is typically obtained by heating of a metal resting on the material containing GeSn to a temperature sufficient to allow a reaction in the solid state leading to the formation of the compound, as well as a process of diffusion and/or inter-diffusion and/or nucleation involving atoms of the metal. However, as soon as the concentration of the tin is greater than 1% in the germanium, it tends to segregate during the heating, making the source of light or the photodetector ineffective. The segregation of the tin occurs in particular when the temperature exceeds the temperature of epitaxy of the material containing GeSn. Segregation means that atoms of tin leave the crystal lattice of the material containing GeSn to form a phase of pure tin. It is possible to visualise a state of segregation of tin by X-ray diffraction.

The document EP 3 945 545 A1 proposes a solution to create an Ni(GeSn) ohmic contact, limiting, or even eliminating, a phenomenon of segregation of the tin at the ohmic contact. A layer of nickel (Ni) is deposited on a layer made of germanium-tin alloy (GeSn). A layer of titanium nitride (TiN) is then deposited on the layer of nickel. The layer of TiN is illuminated by a pulse laser beam. Most of the energy of the beam is absorbed by the layer of TiN and the heat diffuses towards the layers of Ni and of GeSn, until the melting temperature of the GeSn alloy is exceeded. The laser emits pulses of 160 ns at a wavelength of 308 nm, in an energy range between 0.4 J/cm² and 0.7 J/cm².

A laser such as that used in the document EP 3 945 545 A1 typically has a beam having a cross-section equal to 1 cm² and generally sweeps the plate. There is therefore a risk of the laser heating the active region to a temperature greater than a temperature leading to a phenomenon of segregation of the tin. Moreover, furnaces are heating means generally preferred in the semiconductor industry since they are versatile and allow to reduce the manufacturing costs. Among them, the tools for rapid thermal heating (or Rapid Thermal Annealing, RTA), for example using a lamp, provide numerous advantages.

There is therefore a need for a method for creating an ohmic contact from an intermetallic compound that does not risk deteriorating the active zone of devices containing GeSn. Moreover, it would be advantageous for the method to be able to be implemented in a rapid thermal heating tool.

### DISCLOSURE OF THE INVENTION

The goal of the invention is to at least partly overcome the disadvantages of the prior art, and more particularly to propose a method for manufacturing an optoelectronic device comprising an active region containing an alloy of germanium and tin, and an intermetallic compound having low resistivity, without segregating the tin of the active region.

For this, the object of the invention is a method for manufacturing an optoelectronic device including an ohmic contact. The method comprises a step of epitaxy of a layer of interest containing an alloy of germanium and tin on a growth layer comprising germanium, at an epitaxy temperature Te, such that a minimum concentration of tin in the layer of interest is strictly greater than a maximum concentration of tin in the growth layer, a step of forming an active region in the layer of interest, having a surface extent in a plane parallel to a main plane of the layer of interest smaller than a first predetermined maximum surface area, a healing annealing of the active region to eliminate dislocations of the active region, a step of removing at least a part of the growth layer so that a surface area of the growth layer in contact with the layer of interest and facing the active region is less than a second determined maximum surface area or zero, a step of metallisation to obtain a metallic portion including a metal chosen from titanium or an alloy of platinum and nickel, resting on a part of the layer of interest, a step of heating in a furnace to a temperature Ti strictly greater than the epitaxy temperature Te, to create an intermetallic compound of the ohmic contact from the metallic portion, comprising germanium, tin and the metal. The steps of epitaxy, of forming the active region, of removal, of metallisation and of heating are successive. The first maximum surface area and the second maximum surface area are such that the tin in the active region does not segregate during the heating step and during the healing annealing.

Certain preferred but non-limiting aspects of this manufacturing method are the following.

The removal step can release a compressive mechanical stress in the active region.

A concentration of tin in the active region can be greater than 13%, and a residual compression of the active region after the removal step can be greater than or equal to −0.35%.

The removal step can comprise a transfer of the layer of interest onto an acceptor substrate, followed by a total removal of the growth layer.

The transfer can be carried out by placing a first bonding layer including a metal resting on the layer of interest, chosen from titanium or an alloy of nickel and platinum, in contact with a second bonding layer made of metal resting on the acceptor substrate.

The removal step can comprise an anisotropic etching of a through-hole of the layer of interest, followed by an isotropic etching of the growth layer through the through-hole, selective with respect to the layer of interest.

After the isotropic etching, the growth layer and the layer of interest can define an interface not having a part facing the active region.

The anisotropic etching can define a peripheral part of the layer of interest comprising the interface, and a structured part of the layer of interest including a central portion comprising the active region, connected to the peripheral part by at least two tensor arms opposite to one another with respect to the central portion, and the isotropic etching can induce a tensile stress of the central portion by the tensor arms.

The surface extent of the active region can be defined by an etching sidewall.

The etching sidewall can comprise a crystalline plane (110) or ( [symbol] ) of the layer of interest.

The metal can be titanium, and the temperature Tᵢ of the heating step can be greater than a temperature for which a Ti₆(GeSn)₅ phase is formed.

The metal can be an alloy of platinum and of nickel and the temperature Tᵢ of the heating step can be greater than a temperature for which an NiPt (GeSn) phase is formed.

The manufacturing method can comprise a previous procedure of determining the second maximum surface area comprising the following steps: epitaxy of a first layer containing GeSn of the same nature as the layer of interest, on a second layer of the same nature as the growth layer, removing a part of the second layer to create a set of test structures each comprising an interface between the first and the second layers, the interfaces having different surface areas, implementing the heating step, identifying a subset of the set of test structures for which the tin in the test structure has segregated, defining the second maximum surface area at a value strictly lower than all the surface areas of the interfaces of the test structures of the subset.

The healing annealing and the heating step can be the same single step.

### BRIEF DESCRIPTION OF THE DRAWINGS

Other aspects, goals, advantages and features of the invention will become clearer upon reading the following detailed description of preferred embodiments thereof, given as a non-limiting example, and made in reference to the appended drawings in which:

FIGS. 1A and 1B are cross-sectional diagrams of method steps shared by a first, a second and a fourth manufacturing method according to the invention;

FIGS. 2A to 2F are cross-sectional diagrams of steps of a first manufacturing method according to the invention;

FIGS. 3A to 3C are cross-sectional diagrams of steps of a second manufacturing method according to the invention;

FIGS. 4A to 4E are cross-sectional diagrams of steps of a third manufacturing method according to the invention;

FIGS. 5A to 5C are diagrams of steps of a fourth manufacturing method according to the invention;

FIGS. 6A to 6C are cross-sectional diagrams of steps of a procedure for obtaining a first surface area threshold and a second surface area threshold for segregation of the tin in a layer containing an alloy of germanium and tin.

### DETAILED DISCLOSURE OF SPECIFIC EMBODIMENTS

In the figures and in the remainder of the description, the same references represent identical or similar elements. In addition, the various elements are not shown to scale so as to promote clarity of the figures. Moreover, the various embodiments and variants are not mutually exclusive and can be combined together. Unless indicated otherwise, the terms “substantially”, “about”, “approximately” mean within a 10% margin, and preferably within a 5% margin. Moreover, the terms “between . . . and . . . ” and the like mean that the endpoints are included, unless stated otherwise.

The invention relates to a method for manufacturing an optoelectronic device. The latter comprises an active region made in a crystalline layer of interest containing an alloy of germanium and tin. The active region is entirely contained in the layer of interest. The layer of interest is obtained by epitaxy on a crystalline growth layer containing germanium, optionally comprising a quantity of tin strictly smaller than a quantity of tin of the layer of interest. The active region has a surface extent in a plane parallel to a main plane of the layer of interest. A metallic portion consisting of a metal is deposited on the layer of interest. The whole is heated in a furnace, which can be a rapid heating tool, to create an intermetallic compound comprising GeSn and the metal. The temperature of the heating to form the intermetallic compound in a not-very-resistive phase is strictly greater than the epitaxy temperature, at the risk of segregating the tin contained in the active region. The growth layer is removed before the heating, at least partly, in a zone facing the active region and in contact with the layer of interest. If the growth layer is not entirely removed in the zone, the layer of interest rests on a bearing surface of the growth layer facing the active region.

However, the inventors observed that there is a first threshold relating to the surface extent of the active region, independently of its geometric shape, beyond which, that is to say when the surface extent of the active region is greater than the first threshold, the tin segregates in the active region during the heating to form the intermetallic compound. The inventors also observed that, if the growth layer is not entirely removed in the zone, there is a second threshold relating to the bearing surface, independently of its geometric shape, beyond which the tin segregates in the active region during the heating to form the intermetallic compound.

The method of the invention aims to create a specific intermetallic compound by heating in a furnace of an intermediate structure comprising the active region, the latter having a surface extent and an arrangement preventing the segregation of the tin during the creation of the intermetallic compound. That is to say that the surface extent of the active region is below the first threshold, and the bearing surface is below the second threshold or non-existent, in order to obtain the intermetallic compound from a metallic portion specifically comprising titanium or an alloy of nickel and platinum. Thus, the integrity of the active region is preserved, and the intermetallic compound is not very resistive. The bearing surface, when it is present, and the surface extent of the active region can further be respectively smaller than a second predetermined maximum surface area and a first predetermined maximum surface area, themselves less than or equal, respectively, to the second threshold and to the first threshold. The first and second surface areas are for example predetermined so as to furthermore preserve the integrity of the active region during an additional heating step, for example such as a healing annealing of the active region. The first and second thresholds, as well as the first and second maximum surface areas, depend on numerous parameters, including a concentration of tin in the layer of interest or one or more mechanical stresses in the layer of interest and/or in the growth layer, or a heat budget for creating the intermetallic compound.

The optoelectronic device can for example be a laser, a light-emitting diode or a photodiode. It can be part of a larger assembly, like an integrated photonic circuit. The intermetallic compound is for example a part of an ohmic contact of the optoelectronic device. The ohmic contact can electrically connect the active region to an electric circuit of the optoelectronic device or external to the optoelectronic device, or to a tester.

Layer means here and in the rest of the description an area consisting of one or more sublayers of a material, the thickness of which according to an axis Z is, for example ten times, or even twenty times, less than its longitudinal dimensions of width and of length in a plane (X, Y) perpendicular to the axis Z. A layer can be structured.

Throughout the description, a layer or a material “contains” a semiconductor when the layer or the material comprises for the most part the semiconductor, and optionally one or more additional chemical elements, for example such as doping atoms. Unless otherwise mentioned, the semiconductor is in crystalline form. When the layer comprises several sublayers, each sublayer comprises for the most part the semiconductor. The layer can for example comprise sublayers each comprising for the most part the semiconductor with different quantities of additional chemical element, and/or different additional chemical elements. Thus, a layer containing an alloy of germanium and tin can include a sublayer of intrinsic germanium-tin, interposed between an n-doped sublayer of germanium-tin and a p-doped sublayer of germanium-tin. Likewise, a layer containing germanium can include a stack of sublayers each comprising for the most part germanium and a concentration of tin atoms, the concentration of tin in each sublayer being for example increasing according to an order of the sublayers along an axis perpendicular to a main plane of the layer. Such a layer can be used as a buffer layer to adapt a lattice parameter of a substrate to a lattice parameter of a layer epitaxied on the buffer layer.

Material or layer comprising for the most part a compound means a material or a layer, at least 50% of the volume of which is formed or includes the compound. For example, a layer comprising for the most part an alloy of germanium (Ge) and tin (Sn) can be a layer of material having the empirical formula SiₓGe_{y}Sn_{z} with x<(y+z)/2.

A concentration of a chemical element in a material or a layer is equal to the ratio of the number of atoms of this chemical element to the total number of atoms in the material or the layer. Thus, a layer of an alloy of germanium and tin has a concentration of tin of 13% if the layer consists of 13% tin atoms and 87% germanium atoms.

Throughout the description, when a surface or a surface extent is compared to a value, this

means comparing the surface area of the surface or of the surface extent to the value. Likewise, when a surface or a surface extent is compared to another surface or another surface extent, this means comparing the surface areas of the surfaces or of the surface extents.

An active region of an optoelectronic device is a part of the device intended to emit or to detect a light radiation of interest.

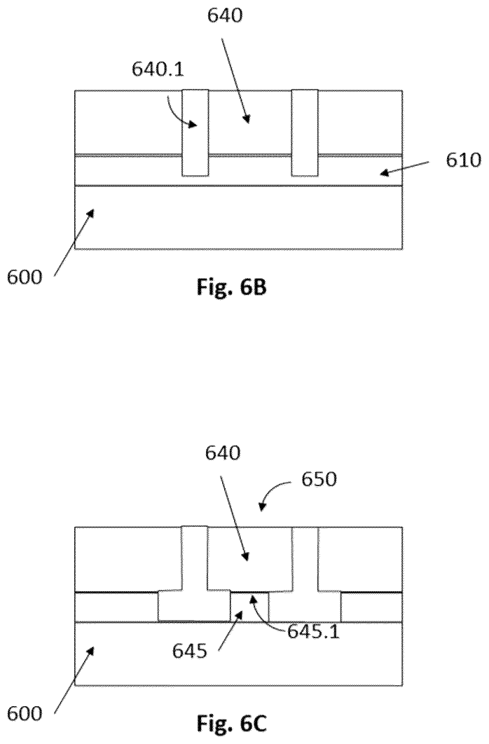

An example of a previous procedure aiming to determine the first and the second thresholds will now be described in relation to FIGS. 6A to 6C. The first and second thresholds are to be determined with regard to a concentration of tin in a first layer 620 containing an alloy of germanium and tin, and a heat budget applied to the first layer 620 at least sufficient to create an intermetallic compound from a metallic portion resting on the first layer 620. The intermetallic compound is not however necessarily created during the procedure.

In FIG. 6A, a second layer 610 containing germanium is grown by epitaxy on a substrate 600, here made of silicon. A first layer 620 containing an alloy of germanium and tin is then grown by epitaxy at an epitaxy temperature Tₑ, on the second layer 610. If the second layer 610 includes tin, a minimum concentration of tin in the first layer 620 is strictly greater than a maximum concentration of tin in the second layer 610.

In FIG. 6B, the first layer 620 is etched by an anisotropic etching over its entire height to create trenches 640.1 exposing the second layer 610. The trenches 640.1 define bases 640 in the first layer 620. The trenches can be extended into the second layer 610, as shown in FIG. 6B. Each base 640 has a surface extent in a main plane of the first layer 620, defined by the trenches, in all the directions of the main plane. The bases 640 have surface extents with different surface areas, and can advantageously be homothetic to each other. The surface extents can be for example discs, rectangles or squares.

In FIG. 6C, the second layer 610 is etched isotropically through the trenches 640.1, selectively with respect to the first layer 620 and advantageously selectively with respect to the substrate 600. A residual part of the second layer 610 after the isotropic etching forms pedestals 645 on which the bases 640 rest, each on a bearing surface 645.1 of the second layer 610. Each bearing surface 645.1 is an interface for growth of the first layer 620 on the second layer 610. A pedestal 645 associated with a base 640 forms a test structure 650. The test structures 650 thus have on the one hand different base surface extents and on the other hand bearing surfaces also different.

The steps of FIGS. 6A to 6C can be reproduced on successive substrates 600, by changing a parameter of the isotropic etching, for example such as an etching time, or a concentration of an etching solution, to obtain a set of test structures 650 having surface extents and bearing surfaces different and independent of each other.

The assembly of the test structures 650 is then heated to a temperature Tᵢ strictly greater than the epitaxy temperature Tₑ. This heating step is for example representative of a heating step for the creation of an intermetallic compound, of a healing annealing of an active region, or of another step requiring a heat budget, like the creation of a stack of interconnections, or the activation of doping atoms, or of a combination of these steps. It should be noted that some of these steps can include shared substeps.

The assembly of test structures 650 is then inspected with an optical microscope. The test structures 650 for which the tin of the base 640 has segregated, and those for which the tin of the base has not segregated, are identified. It is thus established that there is no segregation of the tin for the bases, the surface extent of which is less than a first upper maximum surface area and the bearing surface 645.1 of which is less than a second maximum surface area. The first maximum surface area is strictly less than all of the surface extents of the bases, the tin of which has segregated. The second maximum surface area is strictly less than all of the bearing surfaces of the bases, the tin of which has segregated.

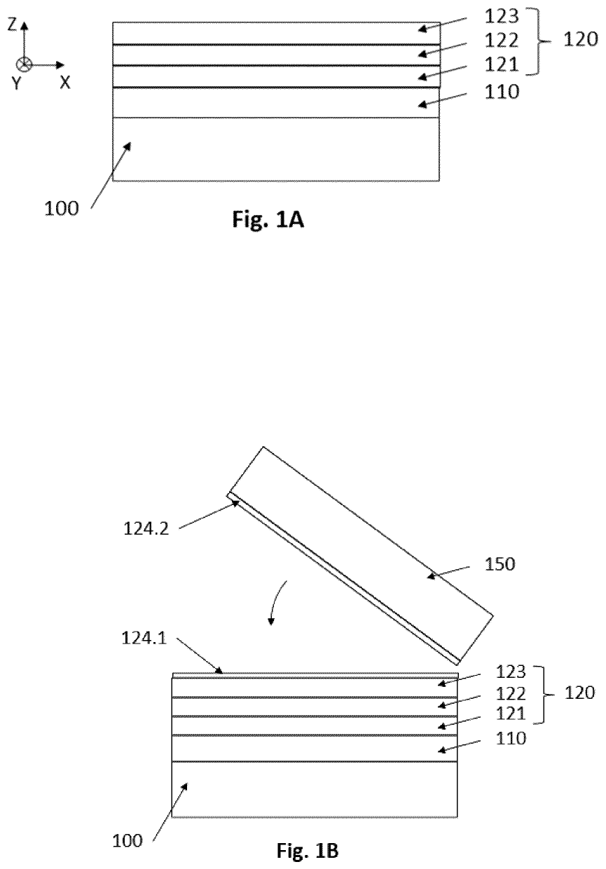

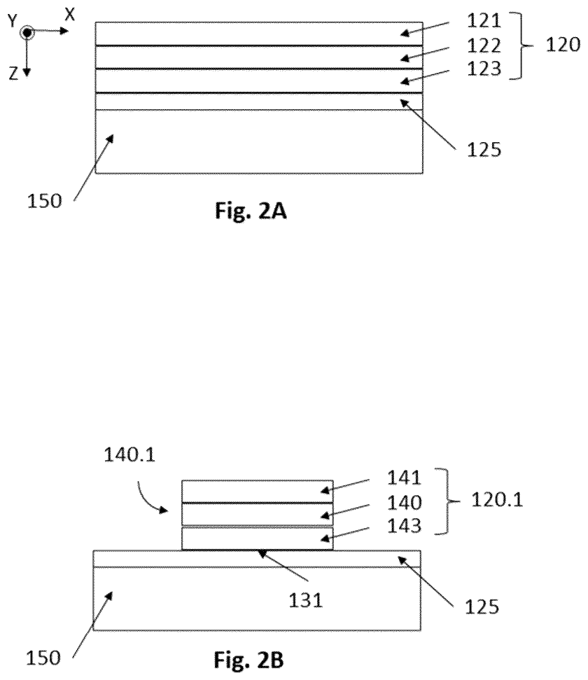

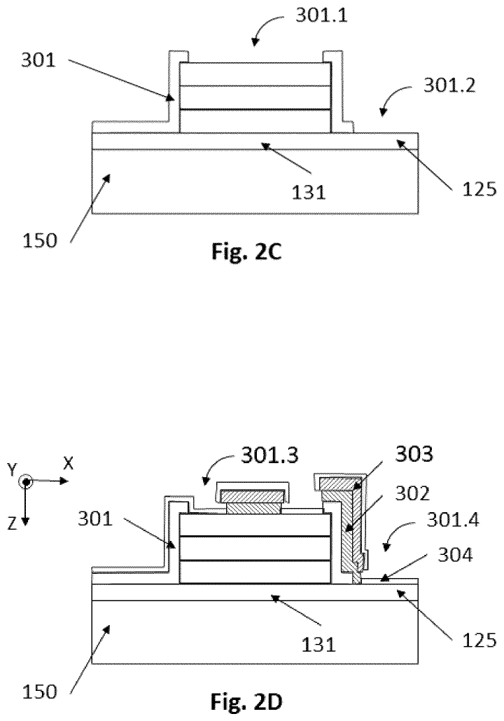

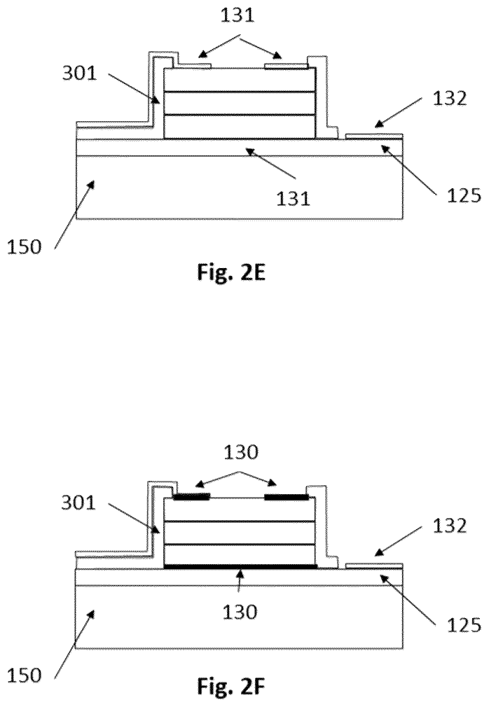

A first method for manufacturing an optoelectronic device will now be described in relation to FIGS. 1A, 1B, 2A to 2F. The optoelectronic device 1 here can be a light-emitting diode or a photodiode.

In FIG. 1A, a buffer layer 110 containing germanium is grown by epitaxy on a substrate 100, here made of silicon having a crystallographic orientation (100). The substrate 100 has a substantially flat upper face parallel and opposite to a lower face, also flat. The substrate 100 extends in a main plane.

Here and in the rest of the description an orthogonal three-dimensional right-handed coordinate system (X, Y, Z), in which the axes X and Y form a plane parallel to the main plane of the substrate 100, and in which the axis Z is oriented from the substrate 100 towards the buffer layer 110, in a direction substantially orthogonal to the main plane of the substrate 100, is defined here. In the rest of the description, the terms “vertical” and “vertically” are meant as being relative to an orientation substantially parallel to the axis Z, and the terms “horizontal” and “horizontally” as being relative to an orientation substantially parallel to the plane (X, Y). Moreover, the terms “lower” and “upper” are meant as being relative to an increasing positioning when moving away from the substrate 100, according to the direction +Z.

The buffer layer 110 comprises here several sublayers. In the order of appearance in the direction of the axis +Z, it can comprise a lower sublayer made of germanium, a first sublayer made of germanium-tin and a second sublayer made of germanium-tin having an average concentration of tin strictly greater than an average concentration of tin of the first sublayer. The thickness of the sublayer of germanium is greater here than the critical thickness, for example equal to 2.5 μm. A mechanical stress of the sublayer of germanium is thus plastically released. The thickness of the first sublayer is between 50 nm and 500 nm, with a concentration of tin between 5 and 8. The thickness of the second sublayer is between 50 nm and 500 nm, with a concentration of tin between 8 and 12.

Alternatively, the buffer layer 110 can consist only of the lower sublayer of germanium or comprise any given number of sublayers of germanium-tin, the concentration of tin in each sublayer thus being increasing in the order of appearance of the sublayers in the direction of the axis +Z. It is also possible for the buffer layer 110 to be a single layer comprising germanium and a concentration of tin gradually increasing in the direction of the axis +Z.

A crystalline layer of interest 120 made of germanium-tin is then epitaxied on the buffer layer 110 at an epitaxy temperature Tₑ. The buffer layer 110 is a “growth” layer, because it is adapted to growing the crystalline layer of interest 120. The thickness of the layer of interest 120 can be strictly less than a critical thickness beyond which a plastic deformation takes place. It has a concentration of tin atoms greater than 1% relative to the number of germanium atoms. The minimum concentration of tin atoms in the layer of interest 120 relative to the number of germanium atoms is in particular strictly greater than a maximum concentration of the buffer layer 110 relative to the number of germanium atoms. Thus, the layer of interest 120 is stressed in compression.

Throughout the description, if the optoelectronic device 1 is a photodiode, the minimum concentration of the layer of interest 120 can be between 2% and 20%. If the optoelectronic device 1 is a light-emitting diode or a laser, the minimum concentration of the layer of interest 120 can be between 6% and 20%.

Here and throughout the description, a minimum (respectively maximum) concentration of a compound in a layer is equal to the minimum (respectively maximum) reached by the average concentration of the compound in each plane parallel to the plane (X, Y) of the layer, along the axis Z.

A method for growth by epitaxy adapted to the growth of the buffer layer 110 is described in the document J. Aubin et al., “Growth and structural properties of step-graded, high Sn content GeSn layers on Ge”, Semiconductor Science and Technology 32, 094006 (2017).

The layer of interest 120 consists here of 3 sublayers: an intrinsic or slightly doped active sublayer 122 interposed between a lower sublayer 121 doped in situ with a first type of conductivity and an upper sublayer 123 doped in situ with a second type of conductivity opposite to the first type of conductivity. The first type of conductivity is of the n type here. A method for growth by epitaxy adapted to the growth of the layer of interest 120, with its sublayers doped in situ, is described in the document M. Frauenrath et al. “Advances in In Situ Boron and Phosphorous Doping of SiGeSn”, ECS J. Solid State Sci. Technol. 2023, 12 064001. The epitaxy temperature Tₑ is typically between 301° C. and 349° C. The epitaxy can for example be carried out by remote plasma chemical vapour deposition (or RPCVD). It decreases with the concentration of tin in the epitaxied layer.

In FIG. 1B, a first bonding layer 124.1 is deposited on the layer of interest 120 and a second bonding layer 124.2 is deposited on an acceptor substrate 150. On faces opposite to, respectively, the layer of interest 120 and the acceptor substrate 150, the first and the second bonding layer 124.1, 124.2 can both comprise a dielectric, preferably amorphous, for example such as silicon oxide (SiO) or silicon nitride (SiN), or, alternatively both, a metal, for example chosen from titanium (Ti), copper (Cu), chromium (Cr), gold (Au) or an alloy of these metals. Thus, the first bonding layer 124.1 can be bonded to the second bonding layer 124.2 by a technique of direct bonding.

Moreover, advantageously, the first bonding layer 124.1 includes titanium (Ti) or an alloy

of nickel and platinum (NiPt) or a bilayer of platinum (Pt) and of nickel (Ni) in contact with the layer of interest 120, in the latter case, the platinum is preferably in contact with the layer of interest 120. When the first bonding layer 124.1 includes an alloy of platinum and titanium, the concentration of platinum atoms is typically between 5% and 15%, preferably equal to 10%, relative to the number of nickel atoms. If the acceptor substrate 150 is made of silicon, the second bonding layer 124.2 can comprise a native silicon oxide, deposited or thermal, in contact with the acceptor substrate 150.

In this example, the first bonding layer 124.1 consists of 3 sublayers, with in the order of appearance from the layer of interest 120, a sublayer 10 nm thick made of titanium (Ti), a sublayer 10 nm thick made of titanium nitride (TiN) and a sublayer made of gold (Au) having a thickness greater than or equal to 200 nm, for example between 200 nm and 1 μm, or between 400 nm and 1 μm.

In this example, the acceptor substrate 150 is made of silicon and the second bonding layer 124.2 consists of 2 sublayers, a sublayer of chromium (Cr) 10 nm thick, interposed between a 200 nm layer of gold (Au) and the acceptor substrate 150.

The first bonding layer 124.1 and the second bonding layer 124.2 are then placed in contact and adhere to one another to assemble the acceptor substrate 150 to the substrate 100 via the buffer layer 110, the layer of interest 120, the first bonding layer 124.1 and the second bonding layer 124.2. After this step, the first bonding layer 124.1 and the second bonding layer 124.2 together define a metal layer 125. Consequently, the metal layer 125 advantageously includes titanium (Ti) or an alloy of nickel and platinum (NiPt) or a bilayer of platinum (Pt) and of nickel (Ni) in contact with the layer of interest 120, in the latter case, the platinum is preferably in contact with the layer of interest 120. In this example, the assembly is carried out by thermocompression at 150° C. for 60 minutes, while applying a force equivalent to 1 tonne.

In FIG. 2A, the substrate 100 is removed. In this example, to remove the substrate 100, a step of grinding and/or polishing is carried out to leave a residual thickness of the substrate 100 of approximately 100 μm, followed by an etching step. The buffer layer 110 is then removed entirely, so as to eliminate misfit dislocations in the layer of interest 120, near an interface between the buffer layer 110 and the layer of interest 120. In this example, the buffer layer 110 is removed during an isotropic etching by a sulphur hexafluoride (SF6) and/or carbon tetrafluoride (CF4) plasma. It should be noted that in FIGS. 2A to 2F, the axis Z of the right-handed orthogonal coordinate system (X, Y, Z) is oriented from the layer of interest towards the acceptor substrate 150.

The inventors have observed that misfit dislocations near the interface between the buffer layer 110 and the layer of interest 120 initiate an accumulation of tin under the effect of a heating. The tin then migrates towards the surface by the channel of threading dislocations to diffuse along a direction [110] of the layer of interest 120. A sustained phenomenon of segregation of the tin can thus be created. This phenomenon can be, at least partly, avoided by the elimination of misfit dislocations induced by an at least partial removal of the buffer layer 110, here total, and can be stopped by the arrangement of an edge of the layer of interest 120 in a crystalline plane orthogonal to the direction [110].

In FIG. 2B, the layer of interest 120 is etched locally over its entire thickness by an anisotropic etching, to obtain a structured layer of interest 120.1. After this step, the structured layer of interest 120.1 comprises an etching sidewall 140.1 substantially perpendicular to the plane (X, Y) that defines a region of the layer of interest 120 intended to be an active region 140 of the optoelectronic device 1. The layer of interest 120 is etched here by a plasma of a gaseous mixture of CF₄, N₂ and O₂, through a mask of photosensitive resin obtained by photolithography. The etching sidewall 140.1 also defines a first doped region 141 having the first type of conductivity, coming from the lower sublayer 121, and a second doped region 143 having the second type of conductivity, coming from the upper sublayer 123. The first and second doped regions 141, 143 are intended to become p and n doped regions of a PIN diode of the optoelectronic device 1.

A part of the metal layer 125 in contact with the structured layer of interest 120.1 defines a metallic portion 131 intended to create an intermetallic compound.

The structured layer of interest 120.1 can have over its entire height a rectangular or elliptical or circular cross-section in a plane substantially parallel to the plane (X, Y). The etching sidewall 140.1 thus has a shape, respectively, rectangular, elliptical or circular, in this plane. The active region 140 has a surface extent in a plane parallel to the plane (X, Y) defined by the etching sidewall 140.1.

Optionally, the structured layer of interest 120.1 can be subjected to a “healing” annealing in a furnace, for more than 5 minutes, at a temperature T_{g} strictly greater that the epitaxy temperature Tₑ. The temperature T_{g} is for example greater than or equal to 350° C. Thus, crystalline defects in the structured layer of interest 120.1 and in the active region 140 are eliminated. These defects include for example threading dislocations and/or holes and/or interstitial atoms resulting from the step of epitaxy of the layer of interest 120. The optional healing annealing is advantageously carried out after obtaining the structured layer of interest 120.1, but it can also be of interest to carry it out at other moments of the method.

Alternatively, the anisotropic etching of the layer of interest 120 occurs after the deposition of the first bonding layer 124.1 and before the assembly of the acceptor substrate 150 with the substrate 100. For this alternative, the first bonding layer 124.1 is structured and has a geometry substantially identical to the structured layer of interest 120.1 in a plane parallel to the plane (X, Y). The first bonding layer 124.1 thus structured, and the second bonding layer 124.2, are then placed in contact and adhere to one another to assemble the acceptor substrate 150 to the substrate 100 via the buffer layer 110, the layer of interest 120, the first bonding layer 124.1 and the second bonding layer 124.2. After this step, the first bonding layer 124.1 and the second bonding layer 124.2 together define a structured metal layer 125. A part of the metal layer 125 in contact with the structured layer of interest 120.1 defines a metallic portion 131 intended to create an intermetallic compound. The assembly can be carried out by thermocompression at a temperature between substrate 100° C. and 250° C., for example equal to 150° C., for 60 minutes, while applying a force equivalent to 1 tonne. The substrate is then removed as described in relation to FIG. 2A. Only the optional healing annealing can optionally be carried out in the step of FIG. 2B. The method of this alternative continues as described in relation to FIGS. 2C to 2F.

In FIG. 2C, an insulating coating 301 is conformally deposited on the structured layer of interest 120.1 and the metal layer 125. A first opening 301.1 and a second opening 301.2, both passing all the way through, are made in the insulating coating 301 to expose respectively the layer of interest 120 and the metal layer 125. The first and second openings 301.1, 301.2 extend in planes substantially parallel to the plane (X, Y). The insulating coating 301 is advantageously a layer for passivation of the structured layer of interest 120.1. It passivates in particular the active region 140 on the etching sidewall 140.1. The insulating coating 301 can be a dielectric. It typically has a thickness of 10 to 300 nm, preferably of 150 to 200 nm. The insulating coating 301 is made of silicon oxide here, for example made of SiO₂.

In FIGS. 2D and 2E, metallic portions 131 and an additional metallic portion 132 are

created by a lift-off lithography method known to a person skilled in the art. It should be noted that the metallic portions 131 and the additional metallic portion 132 can also be obtained by steps of masking by photolithography and conventional dry etchings. The additional metallic portion 132 is optional.

In FIG. 2D, a bilayer of resins 302, 303 is exposed and developed, so as to define patterns of resin having inward-sloping edges. A pattern of resin and the insulating coating 301 together define a third opening 301.3 inside the first opening 301.1, exposing the structured layer of interest 120.1 in a plane substantially parallel to the plane (X, Y). Optionally, the metal layer 125 is exposed at a fourth opening 301.4, inside the second opening 301.2.

A metallic coating 304 is then deposited conformally. The metallic coating 304 is thus in contact with the structured layer of interest 120.1 at the third opening 301.3. It is also in contact with the metal layer 125 at the fourth opening 301.4, when the latter exists. The metallic coating 304 advantageously includes titanium (Ti) or an alloy of nickel and platinum (NiPt) or a bilayer of platinum (Pt) and nickel (Ni) in contact with the structured layer of interest 120.1. In this example, the metallic coating 304 consists of three sub-coatings, a 7 nm sub-coating of titanium nitride (TiN) interposed between a 10 nm sub-coating of titanium (Ti) in contact with the structured layer of interest 120.1, and a 400 nm sub-coating of gold (Au).

The patterns of resin are then removed (FIG. 2E), for example by dilution in acetone for 25 minutes, at 40° C., at the same time as the parts of the metallic coating 304 resting on the patterns of resin. After this step, each part of the metallic coating 304 in contact with the structured layer of interest 120.1 in the third opening 301.3 defines a metallic portion 131 intended to create an intermetallic compound. Here, the additional metallic portion 132 consists of the part of the metallic coating 304, initially positioned in the fourth opening 301.4, that rests on the metal layer 125.

FIG. 2F is a step of creating an intermetallic compound 130. The intermediate structure obtained after the method steps of FIG. 2E is heated in a furnace. The heat budget is sufficient to create the intermetallic compound 130 from each metallic portion 131 in contact with the structured layer of interest 120.1, comprising germanium, tin and a metal of the metallic portion 131. The heating step of FIG. 2F is advantageously carried out in a tool for rapid thermal heating (or Rapid Thermal Annealing, RTA).

When the metallic portion 131 comes from a metallic coating 304 and/or from a metal layer 125 including titanium (Ti) or an alloy of nickel and platinum (NiPt) or a bilayer of platinum (Pt) and nickel (Ni), the temperature Tᵢ of the heating step of FIG. 2F is strictly greater than the epitaxy temperature Tₑ. Thus, the heating step of FIG. 2F participates in the elimination of crystalline defects in the structured layer of interest 120.1 and in the active region 140, in addition to or in replacement of the healing annealing. These defects include for example threading dislocations and/or holes and/or interstitial atoms resulting from the step of epitaxy of the layer of interest 120.

If the metallic portion 131 includes an alloy of platinum and nickel (NiPt), the temperature Tᵢ is for example greater than or equal to 350° C., for a duration greater than 10 s, for example equal to 30 s, thus the intermetallic compound 130 comprises an NiPt(GeSn) phase that is not very resistive. If the metallic portion 131 includes titanium (Ti), as is the case in this example, the temperature Tᵢ is for example greater than or equal to 450° C., for a duration greater than 10 s, for example equal to 30 s, thus the intermetallic compound 130 comprises a Ti₆(GeSn)₅ phase that is not very resistive.

The active region 140 has a surface extent smaller than a first maximum surface area and the buffer layer 110 has been entirely removed, so that the tin of the active region 140 does not segregate during the step of creating the intermetallic compound 130. The first maximum surface area can be established by applying the previous procedure described in relation to FIGS. 6A to 6C, with a second layer 610 of the same nature as the buffer layer 110 and a first layer 620 of the same nature as the layer of interest 120. The heat budget of the step of FIG. 2F is applied for the heating of the step of FIG. 6C.

The etching sidewall 140.1 can advantageously comprise a crystalline plane (110) or ( [symbol] ) of the layer of interest 120 to avoid the possible sustained phenomenon of segregation of the tin. The trenches 640.1 during the creation of the test structures of the previous procedure thus all advantageously include a crystalline plane (110) or ( [symbol] ).

The first maximum surface area is for example equal to 2.5·10⁻⁶ cm², for an active region 140

comprising 13% tin and a heat budget corresponding to a temperature of 400° C. for 20 minutes. For an active region 140 comprising 11% tin, the first maximum surface area is equal to 4.5·10⁻⁶ cm² for a heat budget of 400° C. for 20 minutes, and equal to 1.8·10⁻⁶ cm² for a heat budget of 450° C. for 20 minutes. For an active region 140 comprising 16% tin, the first maximum surface area is equal to 1.5·10⁻⁶ cm² for a heat budget of 400° C. for 20 minutes.

In the optoelectronic device 1 made with this first manufacturing method or the following ones, an intermetallic compound 130 in contact with the first doped region 141 is connected to an electric circuit, for example for power supply or control or reading, via a metal contact (not shown) formed on the intermetallic compound 130. The intermetallic compound 130 in contact with the second doped region 143 is connected to the electric circuit via the metal layer 125 and an additional metal contact (not shown), formed on the additional metallic portion 132. The metal contacts can comprise titanium (Ti), gold (Au), aluminium (Al) or an alloy of aluminium and copper (AlCu). Alternatively, the intermetallic compounds 130 can be connected to the electric circuit by a wired connection or probes, for example probes of a tester.

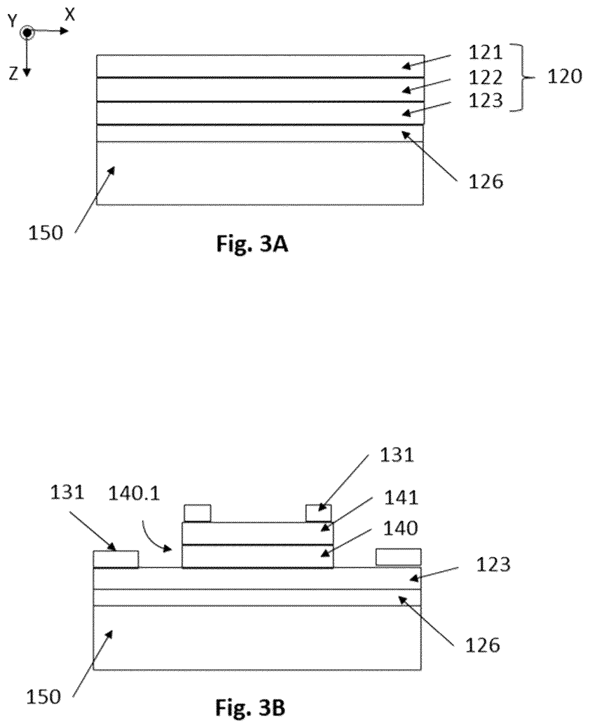

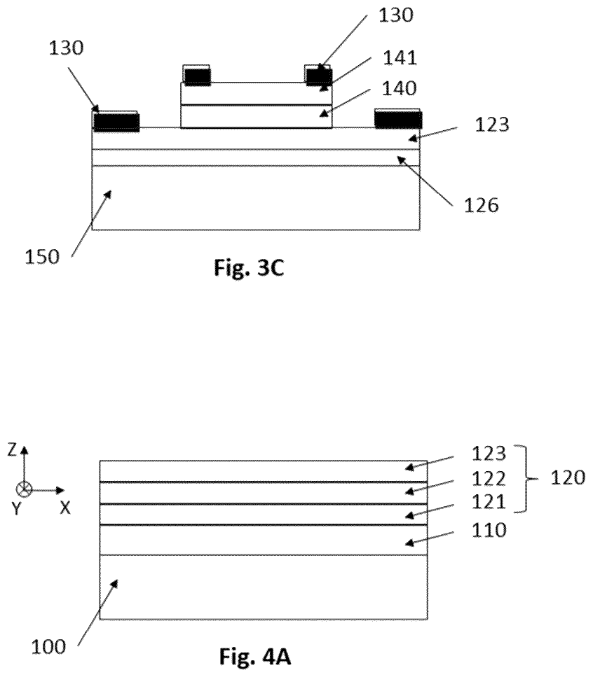

A second method for manufacturing an optoelectronic device will be described in relation to FIGS. 1A, 1B, 3A to 3C. The optoelectronic device 1 here can be a laser or a photodiode, capable of, respectively, emitting or receiving a light flow in a plane substantially parallel to the plane (X, Y). Only the differences with the first method will be explicitly described.

In FIG. 1B, the first and the second bonding layers 124.1, 124.2 are made of a dielectric, here amorphous silicon oxide (SiOₓ). After the assembly of the acceptor substrate 150 with the substrate 100, the first bonding layer 124.1 and the second bonding layer 124.2 together define an insulating layer 126.

In FIG. 3B, the layer of interest 120 is etched locally and partially by an anisotropic etching,

to obtain the layer of interest 120.1. The structured layer of interest 120.1 comprises an etching sidewall 140.1 substantially perpendicular to the plane (X, Y) that defines a region of the layer of interest 120 intended to be an active region 140 of the optoelectronic device 1. The etching sidewall 140.1 also defines a first doped region 141 having the first type of conductivity, coming from the lower sublayer 121. The upper sublayer 123 is preserved at least over a part of its height, advantageously in totality. The first doped region 141 and a part of the upper sublayer 123 facing the first doped region 141 and the active region 140 are intended to become the p and n doped regions of a PIN diode of the optoelectronic device 1. The active region 140 has a surface extent in a plane parallel to the plane (X, Y) defined by the etching sidewall 140.1.

Metallic portions 131 are then created using conventional steps of photolithography and etching. At least one metallic portion 131 rests on the first doped region 141 and another metallic portion 131 rests on another exposed part of the layer of interest 120 located under the upper sublayer 123.

FIG. 3C is a step of creating an intermetallic compound 130. The intermediate structure obtained after the method steps of FIG. 3B is heated in a furnace. The heat budget is sufficient to create the intermetallic compound 130 from each metallic portion 131 in contact with the structured layer of interest 120.1, comprising germanium, tin and a metal of the metallic portion 131. Intermetallic compounds are thus obtained on the upper sublayer 123 and on the first doped region 141.

Like for the first manufacturing method, the active region 140 has a surface extent smaller than a first maximum surface area and the buffer layer 110 has been entirely removed, so that the tin of the active region 140 does not segregate during the step of creating the intermetallic compound 130. The etching sidewall 140.1 can advantageously comprise a crystalline plane (110) of the layer of interest 120 to avoid the possible sustained phenomenon of segregation of the tin.

The first maximum surface area is for example equal to 2.5·10⁻⁶ cm², for an active region 140 comprising 13% tin.

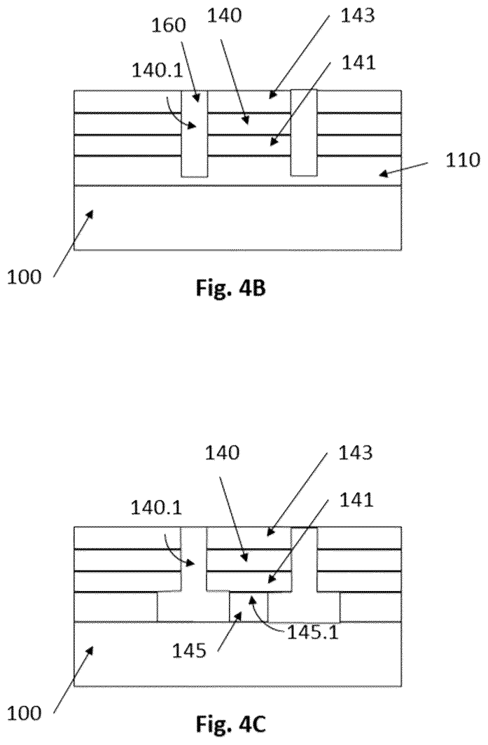

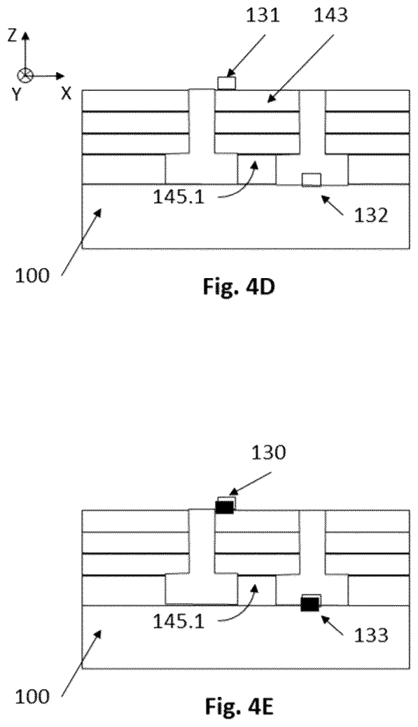

A third method for manufacturing an optoelectronic device will now be described in relation to FIGS. 4A to 4C. The optoelectronic device 1 here can be a laser capable of emitting a light flow in a plane substantially parallel to the plane (X, Y). Only the differences with the first method will be explicitly described.

The step of FIG. 4A is identical to that of FIG. 1A. The first type of conductivity is here the p type. The substrate 100 also comprises a doped layer having the first type of conductivity, made of silicon or containing germanium, on which the epitaxy of the buffer layer 110 is carried out. The buffer layer 110 is doped in situ with the first type of conductivity.

In FIG. 4B, the layer of interest 120 is etched by an anisotropic etching over its entire height to obtain at least one through-hole 160 exposing the buffer layer 110. An etching sidewall 140.1 substantially perpendicular to the plane (X, Y) defines a region of the layer of interest 120 intended to be an active region 140 of the optoelectronic device 1. The layer of interest 120 is etched here by a plasma of a gaseous mixture of CF₄, N₂ and O₂, through a mask of photosensitive resin obtained by photolithography. The etching sidewall 140.1 also defines a first doped region 141 having the first type of conductivity, coming from the lower sublayer 121, and a second doped region 143 having the second type of conductivity, coming from the upper sublayer 123. The first and second doped regions 141, 143 are intended to become the p and n doped regions of a PIN diode of the optoelectronic device 1. The active region 140 has a surface extent in a plane parallel to the plane (X, Y) defined by the etching sidewall 140.1.

In FIG. 4C, the buffer layer 110 is etched isotropically, selectively with respect to the layer of interest 120 and advantageously selectively with respect to the substrate 100. A residual part of the buffer layer 110 after the isotropic etching forms a pedestal 145 on which the first doped region 141 rests, on a bearing surface 145.1 of the buffer layer 110. The bearing surface 145.1 is an interface for growth of the layer of interest 120 on the buffer layer 110.

The isotropic selective etching is for example a plasma etching of CF₄, N₂ and O₂, in an etching chamber at a pressure of 50·10⁻³ Torr, with a gaseous flow rate of 30 sccm of CF₄, 40 sccm of N₂, 50 sccm of O₂. Alternatively, an isotropic etching by a plasma of sulphur hexafluoride (SF6) can be used.

In FIG. 4D, a metallic portion 131 on the second doped region 143 and an additional metallic portion 132 on the substrate 100 are formed, by conventional steps of the semiconductor industry, for example similar to FIGS. 2C to 2E.

FIG. 4E is a step of creating an intermetallic compound 130. The intermediate structure obtained after the method steps of FIG. 4D is heated in a furnace. The heat budget is sufficient to create the intermetallic compound 130 from the metallic portion 131 in contact with the structured layer of interest 120.1, comprising germanium, tin and a metal of the metallic portion 131. An intermetallic compound is thus obtained on the first doped region 141. During this step, an additional intermetallic compound 133 is also obtained on the substrate 100. If the substrate 100 is made of germanium, the additional intermetallic compound 133 can be Ni(Pt)Ge. If the substrate 100 is made of silicon, the additional intermetallic compound 133 can be Ni(Pt)Si.

Like for the first and second manufacturing methods, the surface extent of the active region 140 is smaller than a first maximum surface area. In addition, the buffer layer 110 has been partly removed, so that the bearing surface 145.1 is smaller than a second maximum surface area. The tin of the active region 140 does not therefore segregate during the step of creation of the intermetallic compound 130. The etching sidewall 140.1 can also advantageously comprise a crystalline plane (110) or ( [symbol] ) of the layer of interest 120 to avoid the possible sustained phenomenon of segregation of the tin.

The first maximum surface area and the second maximum surface area can be established by applying the previous procedure described in relation to FIGS. 6A to 6C, with a second layer 610 of the same nature as the buffer layer 110 and a first layer 620 of the same nature as the layer of interest 120. The heat budget of the step of FIG. 4E is applied for the heating of the step of FIG. 6C.

The first maximum surface area and the second maximum surface area are for example respectively equal to 2.5·10⁻⁶ cm², and to 3·10⁻⁸ cm², for an active region 140 comprising 13% tin and a heat budget corresponding to a temperature of 400° C. for 20 minutes. For an active region 140 comprising 11% tin, the first maximum surface area is equal to 4.5·10⁻⁶ cm² for a heat budget of 400° C. for 20 minutes, and equal to 1.8·10⁻⁶ cm² for a heat budget of 450° C. for 20 minutes, the second maximum surface area being greater than or equal to 3·10⁻⁸ cm² for these two heat budgets. For an active region 140 comprising 16% tin, the first maximum surface area and the second maximum surface area are respectively equal to 1.5·10⁻⁶ cm² and to 3·10⁻⁸ cm² for a heat budget of 400° C. for 20 minutes.

The active region 140 of the optoelectronic device 1 created by any one of the first, second and third manufacturing methods can have a compressive mechanical stress, for example equal to −0.35%. The concentration of tin to obtain a direct gap is thus typically greater than 13%. The average concentration of the layer of interest 120 and of the active region 140 is for example between 13% and 16%.

A fourth method for manufacturing an optoelectronic device 1 according to the invention, which this time comprises an active region 140 having a tensile mechanical stress and a concentration of tin greater than 8%, will now be described.

The steps of FIGS. 1A, 1B and 3A are carried out. The insulating layer 126 here is made of silicon oxide. A layer of silicon nitride having a compressive mechanical stress is then deposited on the lower sublayer 121. The layer of silicon nitride is etched over its entire height to create a pad 570 having a compressive mechanical stress.

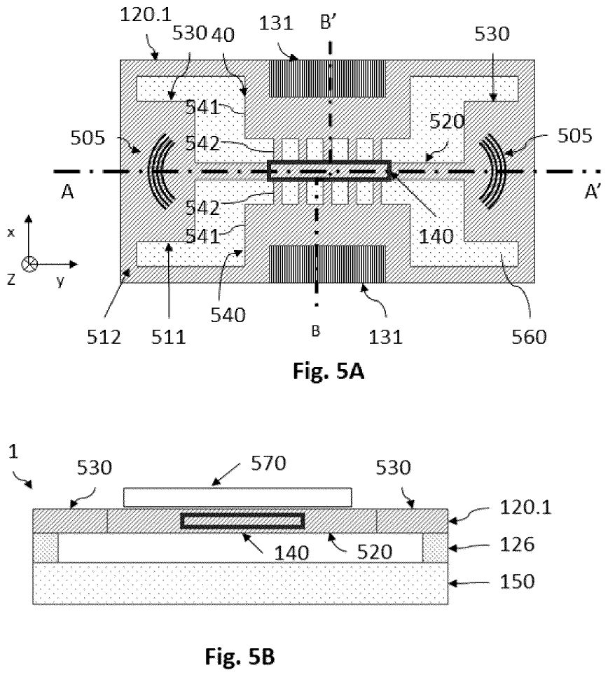

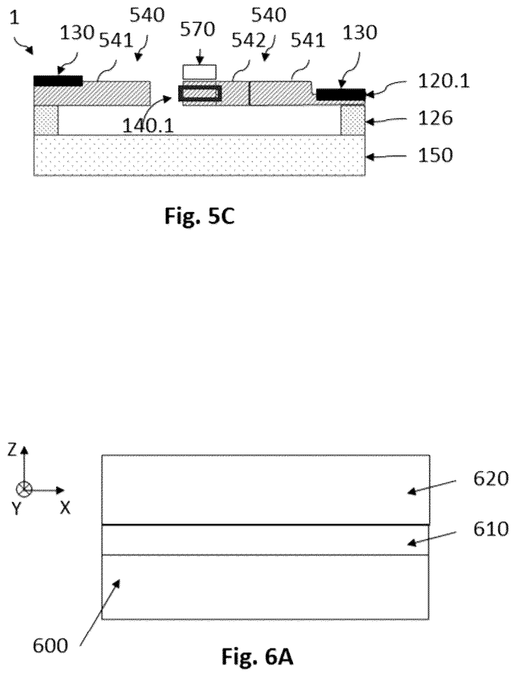

The layer of interest 120 is then locally etched over its entire thickness by an anisotropic etching, to create a through-hole 560 exposing the insulating layer 126. The insulating layer 126 is then etched isotropically, selectively with respect to the layer of interest 120 and the acceptor substrate 150, for example under HF vapour or in an HF solution. After this double etching, a structured layer of interest 120.1 (FIG. 5A) that comprises a structured part 511 suspended above the acceptor substrate 150, and a peripheral part 512 resting on a non-etched part of the insulating layer 126, is obtained. The structured part 511 includes a central portion 520 connected to the peripheral part 512 by first lateral portions 530 forming tensor arms, and by second lateral portions 540 forming electric polarisation arms. The structured part 511 and the peripheral part 512 together form a structured layer of interest 120.1 coming from the layer of interest 120. The pad 570 rests entirely on the central portion 520 and is centred on the latter.

The central portion 520 has an elongated shape in the plane (X, Y), in the sense that it has a length along its longitudinal axis A-A′ that is greater than its width. The length and the width are the dimensions of the central portion 520 in a plane parallel to the plane (X, Y). The shape of the central portion 520 in this plane can be rectangular, polygonal, oblong, or other. The length of the central portion 520 can be approximately several tens of microns, and the width can be approximately several microns. In the case in which the local width of the central portion 520 varies along the longitudinal axis A-A′, the length is then greater than the average width. The tensor arms 530 are opposite to one another with respect to the central portion 520 along the longitudinal axis A-A′.

These tensor arms 530 are dimensions so as to induce, in association with the pad 570, a tensile deformation in the central portion 520 along the longitudinal axis A-A′. They thus extend longitudinally from the central portion 520, along the longitudinal axis A-A′, and more precisely from the longitudinal ends of the latter. Thus, the longitudinal axis A-A′ corresponds to a main axis of deformation of the central portion 520.

Since the central portion 520 is stressed in tension by the tensor arms 530, it thus has a deformation of its crystallographic structure by increase in its natural lattice parameter along the longitudinal axis A-A′. The tensor arms 530 allow to increase the non-zero tensile stress value in the central portion 520 induced by the pad 570, preferably without themselves undergoing a significant mechanical stress. For this, the tensor arms 530 are dimensioned so that the average width “b” of the tensor arms 30 is greater than the average width “a” of the central portion central portion 520, preferably ten times greater than the latter. Width, or local width, means the local dimension of a portion or of an arm, in the plane (X, Y), along a transverse axis orthogonal to the longitudinal axis A-A′. The average width of a portion can thus be an average of its local width calculated over the length of the portion.

The tensor arms 530 can have a substantially rectangular shape in the plane (X, Y), with a sharp increase in its width starting from the central portion 520, or even the shape of a trapezoid with a width that increases continually when moving away from the central portion 520. Other shapes are of course possible, like a triangular shape.

The structured part 511 further includes second lateral portions, forming polarisation arms 540. At least two polarisation arms 540 are disposed on either side of the central portion 520, in a manner opposite to one another along a transverse axis, parallel to the plane (X, Y) and orthogonal to the longitudinal axis A-A′. They therefore extend from lateral borders of the central portion 520 along the transverse axis. In this embodiment, the polarisation arms 540 participate, with the tensor arms 530, in connecting the central portion 520 to the peripheral part 512.

Moreover, each of the polarisation arms 540 includes a main part 541 and a plurality of connection parts 542, the latter ensuring the mechanical and electric link between the main part 541 and the central portion 520. The main part 541 thus has a width greater than that of each connection part 542. The width of the main part 541 here is its dimension in a plane parallel to the plane (X, Y) and along the longitudinal axis A-A′. Moreover, the connection parts 542 are distributed along the axis A-A′, advantageously uniformly. The connection parts 542 extends from a lateral border of the central portion 520 and together define a continuous region along the longitudinal axis A-A′ of the active sublayer 122 and of the central portion 520, intended to be the active region 140 of the optoelectronic device 1. Consequently, the active region 140 has a surface extent in the plane parallel to the plane (X, Y) laterally defined by lateral etching sidewalls 140.1 substantially orthogonal to the plane (X, Y) and parallel to the longitudinal axis A-A′, and longitudinally by the first connection part 542 and the last connection part 542, encountered along the longitudinal axis A-A′. The mechanical stress and the concentration of tin in the active region 140 are such that it has a direct gap.

A metallic portion 131 is formed on a part of the layer of interest 120 at each main part 541

of each polarisation arm 540. More precisely, a metallic portion 131 is formed on a part of the upper sublayer 123 made accessible by a local etching of the lower sublayer 121 and of the active sublayer 122. And, a metallic portion 131 is formed on the lower sublayer 121. Each metallic portion 131 includes titanium (Ti) or an alloy of nickel and platinum (NiPt) or a bilayer of platinum (Pt) and of nickel (Ni) in contact with a part of the layer of interest 120.

The step of creating an intermetallic compound 130 of FIG. 2F is then carried out, applied to the structure obtained after the formation of the metallic portions 131. An intermetallic compound 130 (FIGS. 5B and 5C) is thus obtained on a part of the layer of interest 120 at each main part 541 of each polarisation arm 540. The main part 541 of each polarisation arm 540 is intended to electrically polarise the active region 140 on the basis of the intermetallic compounds 130. FIGS. 5B and 5C are cross-sectional diagrams, respectively, along the axis A-A′ and the axis B-B′, of the structured layer of interest 120.1 on the acceptor substrate 150 of FIG. 5A.

Preferably, to improve the quality of the electric polarisation of the active region 140, the intermetallic compounds 130 are each partly surrounded by an electric insulation line (not shown). An insulation line extends around an intermetallic compound 130 between the latter and the peripheral part 512, and does not extend between said compound and the polarisation arm 540. The insulation lines can be trenches that pass all the way through the layer of interest 120.

Optical reflectors 505, for example Bragg mirrors, can be disposed in the tensor arms 530, on either side of the central portion 520, in order to create a laser diode with electric pumping.

In a first alternative, it is possible to not carry out the steps of FIG. 1B and 3A. The layer made of silicon nitride having a compressive mechanical stress is thus deposited on the upper sublayer 123. And, the buffer layer 110 is etched isotropically, selectively with respect to the layer of interest 120 and, advantageously, selectively with respect to the acceptor substrate 150, instead of etching the insulating layer 126. The part of the buffer layer 110 facing the active region 140 is consequently entirely removed during the step of creating the intermetallic compounds 130.

In a second alternative, it is possible to deposit a layer made of silicon nitride having a tensile mechanical stress instead of the layer made of silicon nitride having a compressive mechanical stress. The pad 570 is thus replaced by two pads 571 coming from the layer made of silicon nitride resting this time on the tensor arms 530, centred on the longitudinal axis A-A′. The second alternative can be used in combination with the first alternative.

In a third alternative, the layer of interest 120 consists of a single layer containing an intrinsic alloy of germanium and tin. The polarisation arms 540 are thus previously implanted before the formation of the metallic portions 131. The polarisation arms 540 have different types of doping. It is not therefore necessary to carry out a partial local etching to make accessible a sublayer of the layer of interest 120 before the formation of the metallic portions 131. The third alternative can be used in combination with the first alternative and/or the second alternative.

For the four manufacturing methods that have just been described, as well as for their alternatives, the metallic portions 131 in contact with a part of the layer of interest 120 advantageously include titanium (Ti) or an alloy of nickel and platinum (NiPt) or a bilayer of platinum (Pt) and of nickel (Ni) in contact with the layer of interest 120, in the latter case, the platinum is preferably in contact with the layer of interest 120. The intermetallic compounds 130 are created in a furnace at a temperature Tᵢ strictly greater than the temperature Tₑ of epitaxy of the layer of interest 120. The step of creating the intermetallic compounds 130 participates in the elimination of crystalline defects in the structured layer of interest 120.1, in addition to or in replacement of a healing annealing at a temperature strictly greater than the temperature Tₑ of epitaxy of the layer of interest 120. These defects include for example threading dislocations and/or holes and/or interstitial atoms resulting from the step of epitaxy of the layer of interest 120.

For the four manufacturing methods, as well as for their alternatives, if the metallic portion 131 includes an alloy of nickel and platinum (NiPt), the temperature Tᵢ is for example greater than or equal to 350° C., for a duration greater than 10 s, for example equal to 30 s, thus the intermetallic compound 130 comprises an NiPt(GeSn) phase that is not very resistive. If the metallic portion 131 includes titanium (Ti), as is the case in this example, the temperature Tᵢ is for example greater than or equal to 450° C., for a duration greater than 10 s, for example equal to 30 s, thus the intermetallic compound 130 comprises a Ti₆(GeSn)₅ phase that is not very resistive. The step of creating the intermetallic compounds 130 is advantageously carried out in a tool for rapid thermal heating (or Rapid Thermal Annealing, RTA).

For the four manufacturing methods, as well as for their alternatives, during the step of

creating the intermetallic compounds 130, the active region 140 has a surface extent smaller than a first maximum surface area and the buffer layer 110 has an interface facing the active region 140 smaller than a second maximum surface area, so that the tin of the active region 140 does not segregate during the step of creating the intermetallic compound 130. For the first, second and fourth manufacturing methods with transfer onto an acceptor substrate 150, the second condition is met by the fact that the buffer layer 110 is entirely removed. For the first alternative of the fourth manufacturing method, the active region 140 is in the suspended central portion 520, consequently, without a residual part of the buffer layer 110 facing the active region 140.

For the four manufacturing methods, as well as for their alternatives, the first maximum surface area and the second maximum surface area can be established by applying the previous procedure described in relation to FIGS. 6A to 6C, with a second layer 610 of the same nature as the buffer layer 110 and a first layer 620 of the same nature as the layer of interest 120. The heat budget of the step of creating the intermetallic compound is applied for the heating of the step of FIG. 6C, optionally with a heat budget for the healing of defects in the active region 140 added thereto.

For the four manufacturing methods, as well as for their alternatives, the active region 140 is defined by at least one etching sidewall 140.1. The etching sidewall 140.1 can advantageously comprise a crystalline plane (110) of the layer of interest 120 to avoid the possible sustained phenomenon of segregation of the tin. The trenches 640.1 during the creation of the test structures of the previous procedure thus all advantageously have a crystalline plane (110) or ( [symbol] ).

For the four manufacturing methods, as well as for their alternatives, each test structure of the previous procedure advantageously has a geometric shape in a main plane of the layer of interest 120 homothetic to a shape of the structured layer of interest 120.1.

Finally, for the four manufacturing methods, the difference between the minimum concentration of tin in the layer of interest 120 and the maximum concentration of tin in the buffer layer 110 can be such that the buffer layer 110 can be removed, at least partly, by selective etching of the buffer layer 110 with respect to the layer of interest 120. An isotropic etching by a plasma of sulphur hexafluoride (SF6) can etch a buffer layer 110 having a maximum concentration of tin lower than 7%, selectively with respect to a layer of interest 120 having a minimum concentration of tin strictly greater than 7%, for example greater than or equal to 8%. An isotropic etching by a plasma of carbon tetrafluoride (CF4) can etch a buffer layer 110 having a maximum concentration of tin lower than 8%, selectively with respect to a layer of interest 120 having a minimum concentration of tin strictly greater than 8%, for example greater than or equal to 9%. An etching of a first material is selective with respect to a second material if the first material is etched at least 5 times faster than the second material, preferably at least 10 times faster.

Specific embodiments have just been described. Various alternatives and modifications will become apparent to a person skilled in the art. They will in particular be perfectly capable of applying the manufacturing methods to obtain an optoelectronic device 1 comprising a PN junction instead and in the place of a PIN junction, the active region 140 thus being perfectly defined by its function. It will also appear to a person skilled in the art that the active region 140 can include one or more quantum wells, for example via jumps in the concentration of tin.

1. Method for manufacturing an optoelectronic device including an ohmic contact, the method comprising:
a step of epitaxy of a layer of interest containing an alloy of germanium and tin on a growth layer comprising germanium, at an epitaxy temperature Tₑ, such that a minimum concentration of tin in the layer of interest is strictly greater than a maximum concentration of tin in the growth layer,
a step of forming an active region in the layer of interest, having a surface extent in a plane parallel to a main plane of the layer of interest smaller than a first predetermined maximum surface area,
a healing annealing of the active region to eliminate dislocations of the active region,
a step of removing at least a part of the growth layer so that a surface area of the growth layer in contact with the layer of interest and facing the active region is less than a second predetermined maximum surface area or equal to zero,
a step of metallisation to obtain a metallic portion including a metal chosen from titanium or an alloy of platinum and nickel, resting on a part of the layer of interest,
a step of heating in a furnace to a temperature Tᵢ strictly greater than the epitaxy temperature Tₑ, to create an intermetallic compound of the ohmic contact from the metallic portion, comprising germanium, tin and the metal;
the steps of epitaxy, of forming the active region, of removal, of metallisation and of heating being successive, and
the first maximum surface area and the second maximum surface area being such that the tin in
the active region does not segregate during the heating step and during the healing annealing.

2. Method according to claim 1, wherein the removal step releases a compressive mechanical stress in the active region.

3. Method according to claim 2, wherein a concentration of tin in the active region is greater than 13%, and a residual compression of the active region after the removal step is greater than or equal to −0.35%.

4. Method according to claim 1, wherein the removal step comprises a transfer of the layer of interest onto an acceptor substrate, followed by a total removal of the growth layer.

5. Method according to claim 4, wherein the transfer is carried out by placing a first bonding layer including a metal resting on the layer of interest, chosen from titanium or an alloy of nickel and platinum, in contact with a second bonding layer made of metal resting on the acceptor substrate.

6. Method according to claim 1, wherein the removal step comprises an anisotropic etching of a through-hole of the layer of interest, followed by an isotropic etching of the growth layer through the through-hole, selective with respect to the layer of interest.

7. Method according to claim 6, wherein, after the isotropic etching, the growth layer and the layer of interest define an interface not having a part facing the active region.

8. Method according to claim 7, wherein the anisotropic etching defines a peripheral part of the layer of interest comprising the interface, and a structured part of the layer of interest including a central portion comprising the active region, connected to the peripheral part by at least two tensor arms opposite to one another with respect to the central portion, and the isotropic etching induces a tensile stress of the central portion by the tensor arms.

9. Method according to claim 1, wherein the surface extent of the active region is defined by an etching sidewall.

10. Method according to claim 9, wherein the etching sidewall comprises a crystalline plane (110) or ( [symbol] ) of the layer of interest.

11. Method according to claim 1, wherein the metal is titanium and the temperature Tᵢ of the heating step is greater than a temperature for which a Ti₆(GeSn)₅ phase is formed.

12. Method according to claim 1, wherein the metal is an alloy of platinum and nickel and the temperature Tᵢ of the heating step is greater than a temperature for which an NiPt(GeSn) phase is formed.

13. Method according to claim 1, comprising a previous procedure of determining the second maximum surface area comprising the following steps:
epitaxy of a first layer containing GeSn of the same nature as the layer of interest, on a second layer of the same nature as the growth layer,
removing a part of the second layer to create a set of test structures each comprising an interface between the first and the second layers, the interfaces having different surface areas,
implementing the heating step,
identifying a subset of the set of test structures for which the tin in the test structure has segregated,
defining the second maximum surface area at a value strictly lower than all the surface areas of the interfaces of the test structures of the subset.

14. Method according to claim 1, wherein the healing annealing and the heating step are one and the same step.
